(19) United States
(12) Patent Application Publication
(10) Pub. No.: US 2012/0069496 A1
(43) Pub. Date: Mar. 22, 2012

(54) SYSTEM AND METHOD FOR DEVICE STABILIZATION

(75) Inventors: Ling Jun Wong, Escondido, CA (US); True Xiong, San Diego, CA (US)

(73) Assignee: Sony Corporation, Tokyo (JP)

(21) Appl. No.: 12/887,395

(22) Filed: Sep. 21, 2010

(51) Int. Cl. H05K 7/00

(52) U.S. Cl. 361/679.01

(57) ABSTRACT

Methods and devices are provided for stabilizing devices. In one embodiment, a device stabilizer comprises a housing, a mounting structure for an electronic device, the mounting structure supported by the housing and configured to secure an electronic device and a dampening element configured to stabilize motion of the mounting structure with respect to the housing. The device stabilizer may further include a counteracting element configured to control the arrangement of the mounting structure within the housing.

### FIELD

The present disclosure relates generally to stabilization of a device, and more particularly to mounting structures for stabilizing electronic devices and displays.

### BACKGROUND

Many users enjoy the use of electronic devices employing displays. One drawback of conventional devices, and in particular devices including displays, relates to shaking or movement of the device during user operation due to motion. Typically, user operation of a device while walking, in a vehicle (e.g., automobile, train, plane, etc.) may result in displacement of the electronic device. Displacement of the device can interrupt user operation of a device. In particular, users of electronic devices displaying text may find operation of the device difficult when moving in a vehicle. Although the user may be standing or seating in a particular position, an electronic device may shift due to motion of the vehicle. As a result of viewing the electronic device while in motion, users may experience difficulty operating the device and in some cases even motion sickness. What is desired is a solution that allows for operation of an electronic device that minimizes and/or cancels motion to the device during operation.

### SUMMARY OF THE EMBODIMENTS

Disclosed and claimed herein are devices configured for stabilization. In one embodiment, device stabilizer comprises a housing, a mounting structure for an electronic device, the mounting structure supported by the housing and configured to secure an electronic device, and a dampening element configured to stabilize motion of the mounting structure with respect to the housing. The stabilizing device includes a counteracting element configured to control the arrangement of the mounting structure within the housing.

According to another embodiment, an electronic device comprises a housing, a display, the display supported by the housing, and a dampening element configured to stabilize motion of the display with respect to the housing. The electronic device includes a counteracting element configured to control the arrangement of the display within the housing.

Other aspects, features, and techniques of the disclosure will be apparent to one skilled in the relevant art in view of the following detailed description of the disclosure.

### BRIEF DESCRIPTION OF THE DRAWINGS

The features, objects, and advantages of the present disclosure will become more apparent from the detailed description set forth below when taken in conjunction with the drawings in which like reference characters identify correspondingly throughout and wherein:

FIG. 1 depicts a graphical representation of a device stabilizer according to one embodiment of the disclosure;

FIG. 2 depicts a graphical representation of a device stabilizer according to another embodiment of the disclosure;

FIG. 3 depicts a graphical representation of a device stabilizer according to another embodiment of the disclosure;

FIG. 4 depicts a graphical representation of a device stabilizer according to another embodiment of the disclosure;

FIGS. 5A-5C depict graphical representations of a device stabilizers according to another embodiment of the disclosure;

FIG. 6 depicts a graphical representation of an electronic device according to one embodiment of the disclosure; and

FIGS. 7A-7B depict a graphical representation of an electronic device according to another embodiment of the disclosure.

### DETAILED DESCRIPTION OF THE EMBODIMENTS

### Overview and Terminology

One aspect of the present disclosure relates to a device stabilizer. In one embodiment, a device stabilizer may be provided to minimize motion or vibration applied to a device supported by the device stabilizer. By way of example, a device stabilizer as described herein may include a housing and a mounting structure. The mounting structure may be configured to secure an electronic device, such as an eReader, media player or electronic device having a display, in a moveable manner to a housing. The stabilizing device may allow the mounting structure to be displaced to minimize or cancel motion of the device secured by the mounting structure. The device stabilizer may include one or more dampening units and one or more counteracting elements to control motion of the mounting structure. In one embodiment, the device stabilizer may allow for one or more of angular displacement and motion in three-dimensions within a housing of the electronic device. In another embodiment, the device stabilizer may be configured to secure an electronic device in a fixed position.

According to another embodiment, an electronic device is provided including a display and one or more elements to control motion of the display within a housing of the electronic device. The electronic device may employ one or more dampening elements and counteracting elements to control motion of the display. In one embodiment, the electronic device may allow for one or more of angular displacement and motion in three-dimensions within a housing of the electronic device. In another embodiment, the electronic device may employ one or more elements of a device stabilizer as described herein. In another embodiment, the electronic device stabilizer may be configured to secure the display in a fixed position.

As used herein, the terms “a” or “an” shall mean one or more than one. The term “plurality” shall mean two or more than two. The term “another” is defined as a second or more. The terms “including” and/or “having” are open ended (e.g., comprising). The term “or” as used herein is to be interpreted as inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment,” “certain embodiments,” “an embodiment,” or similar term means that a particular feature, structure, or characteristic described in connection with the embodiment is included in at least one embodiment of the present disclosure. Thus, the appearances of such phrases in various places throughout this specification are not necessarily all referring to the same embodiment. Furthermore, the particular features, structures, or characteristics may be combined in any suitable manner on one or more embodiments without limitation.

### Exemplary Embodiments

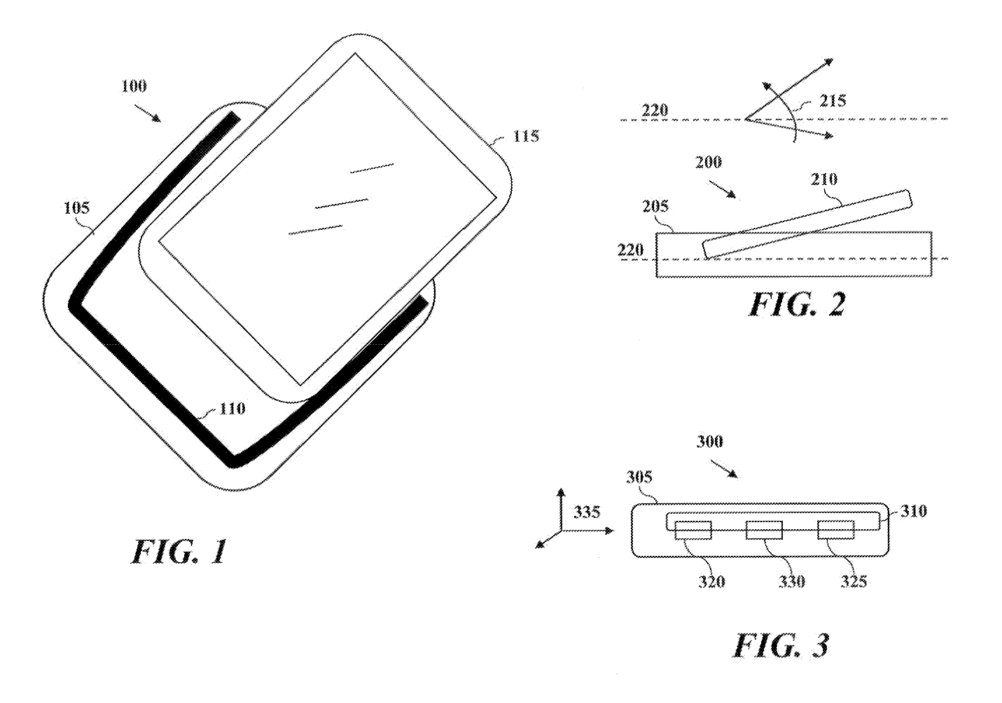

Referring now to the figures, FIG. 1 depicts a graphical representation of a device stabilizer according to one or more embodiments of the disclosure. In one embodiment, device stabilizer 100 may be configured to stabilize an electronic device. As depicted in FIG. 1, device stabilizer 100 includes housing 105 and mounting structure 110. According to one embodiment, device stabilizer 100 may be configured to support one or more different types of electronic device, such as an eReader, media player, gaming device, and electronic devices in general. In certain embodiments, housing 105 may be produced based on the type of electronic device to support. As depicted, mounting structure 105 may be configured to receive and support electronic device 115. Electronic device 115 may relate to an electronic reader, or eReader. As will be discussed here, device stabilizer 100 may be configured to minimize the motion or shaking of electronic device 115 based on one or more external forces to housing 105.

In one embodiment, mounting structure 110 may be supported by housing 105 and configured to secure electronic device 115. Mounting structure 110 may be movable with respect to the housing 105. In one embodiment, housing 105 may be configured to allow for angular displacement of mounting structure 110. According to another embodiment, housing 105 may be configured to suspend the mounting structure 110 to allow for movement. Mounting structure 110 may include a slot configured to receive electronic device 115.

As will be discussed in more detail below with respect to FIG. 3, stabilizer device 100 may include one or more dampening elements and counteracting elements. The dampening element of device stabilizer 100 may be configured to stabilize motion of mounting structure 110 with respect to the housing 105. The dampening element may relate to one or more of an electrical and mechanical dampening element to absorb one or more external forces and vibration causing movement of mounting structure 110. According to another embodiment, device stabilizer 100 may include a counteracting element configured to control the arrangement of mounting structure 110 within the housing 105. The counteracting element may be configured to apply a force to mounting structure 110 opposite to a direction of mounting structure movement. The counteracting element may be activated when an external force applied to mounting structure 110 is above a threshold. In certain embodiments, dampening and counteracting may be provided by a single type of element. For example, mounting structure 110 may be flexibly coupled to housing 105 via one or more electrical or electromechanical dampening controls. In another embodiment, device stabilizer 100 may be configured to secure an electronic device in a fixed position.

Referring now to FIG. 2, a graphical representation is depicted of a device stabilizer according to one embodiment. As depicted in FIG. 2, device stabilizer 200 includes housing 205 and mounting structure 210. Device stabilizer 200 may be configured to allow for angular displacement of mounting structure 210 as shown by 215. Mounting structure 210 may be displaced relative to a starting position depicted by 220. According to one embodiment, mounting structure may be angularly displaced either above or below reference line 220. movement of mounting structure 210 relative to housing 205 may be controlled by at least one dampening element and at least one counteracting element. As depicted in FIG. 2, device stabilizer 200 allows for movement of mounting structure 210 within the housing and external to the housing.

Referring now to FIG. 3, a graphical representation is depicted of a device stabilizer according to one embodiment. As depicted in FIG. 3, device stabilizer 300 includes housing 305 and mounting structure 310. Device stabilizer 300 may be configured to allow for displacement of mounting structure 310 relative to housing 310 in three-dimensions as shown by 315. As depicted in FIG. 3, device stabilizer 300 allows for movement of mounting structure 310 within the housing.

As depicted in FIG. 3, device stabilizer 300 includes dampening elements 320 and 325 configured to stabilize motion of mounting structure 305 with respect to the housing 310.

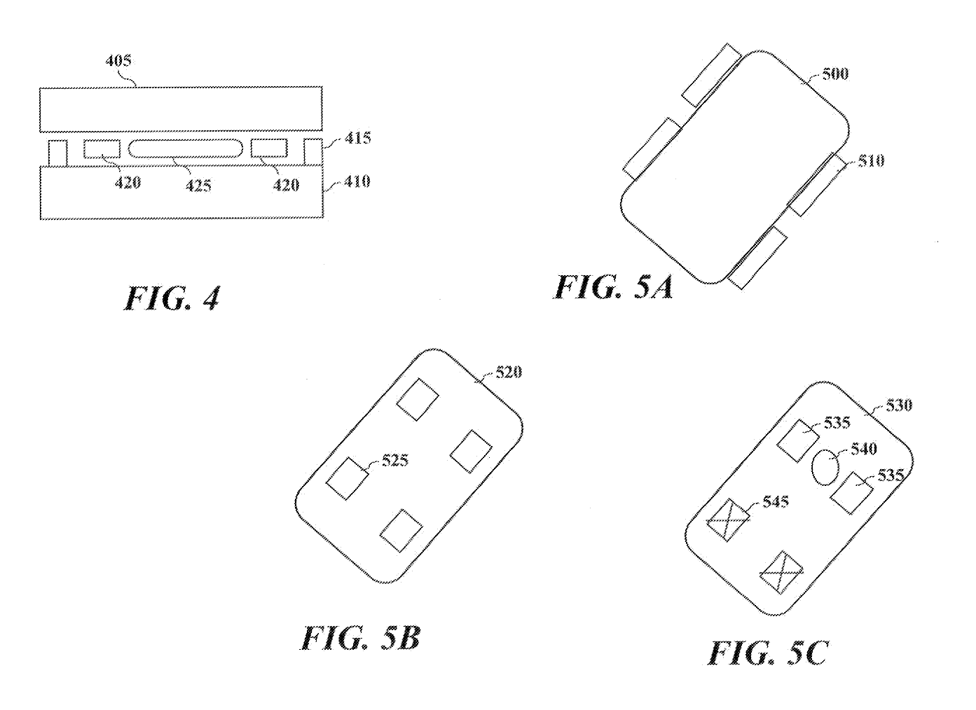

Referring now to FIG. 4, a graphical representation is depicted of a device stabilizer according to another embodiment. As depicted in FIG. 4, device stabilizer 400 includes mounting structure 405 and housing 410. According to one embodiment, mounting structure 405 may be configured to move relative to housing 410 to provide a stabilizing device which may minimize or cancel external motion (e.g., motion due to travel in a vehicle, walking, etc.). Device stabilizer 400 includes one or more sensors depicted as 415, dampening elements depicted as 420 and a counteracting element depicted as 425. Based on movement of mounting structure 405 dampening elements 420 may be configured to restrict or minimize the motion relative to housing 410. Dampening elements 420 may relate to spring based joints in one embodiment. In another embodiment, dampening elements 420 may relate to a friction based elements, wherein the greater force applied to housing 110 relates to increased friction generated by the dampening elements. In one embodiment sensors 415 may be configured to detect position of mounting structure 405 to determine an amount of counteracting by counteracting element 425. For example, sensors 415 may detect an offset of mounting structure 405 relative to housing 410, and provide one or more control signals to counteracting element 425. Counteracting element 425 may apply a force to mounting structure 405 in a direction opposite of force moving the structure to minimize or cancel motion and/or vibration of the mounting structure. Device stabilizer 400 may be configured to allow for one or more of angular displacement and three-dimensional motion of mounting structure 405 relative to housing structure 410 as shown by 415.

Referring now to FIGS. 5A-5B, graphical representations are depicted of device stabilizer configurations according to one or more embodiments. Referring first to FIG. 5A, a graphical representation is depicted of an arrangement for suspending a mounting structure. Mounting structure 500 may be suspended form a housing (not shown in FIG. 5A) from a plurality of elements depicted as 510. In one embodiment, elements 510 may be configured for one or more of dampening, and counteracting motion of a mounting structure.

Referring now to FIG. 5B, a graphical representation is depicted of a stabilizing device according to another embodiment. Mounting structure 520 includes one or more elements 525 which may be mounted below a mounting structure to couple the mounting structure to a housing (not shown in FIG. 5B). In one embodiment, elements 525 may be configured for one or more of dampening and counteracting motion of a mounting structure. Referring now to FIG. 5C, a graphical representation is depicted of a stabilizing device according to another embodiment. Mounting structure 530 includes one or more dampening elements depicted as 535 and a counter activity element depicted as 540. One or more elements 545 which may be mounted below a mounting structure to couple the mounting structure to a housing (not shown in FIG. 5B). In one embodiment elements 545 may allow for angular displacement of mounting structure 535 relative to a housing (e.g., housing 205).

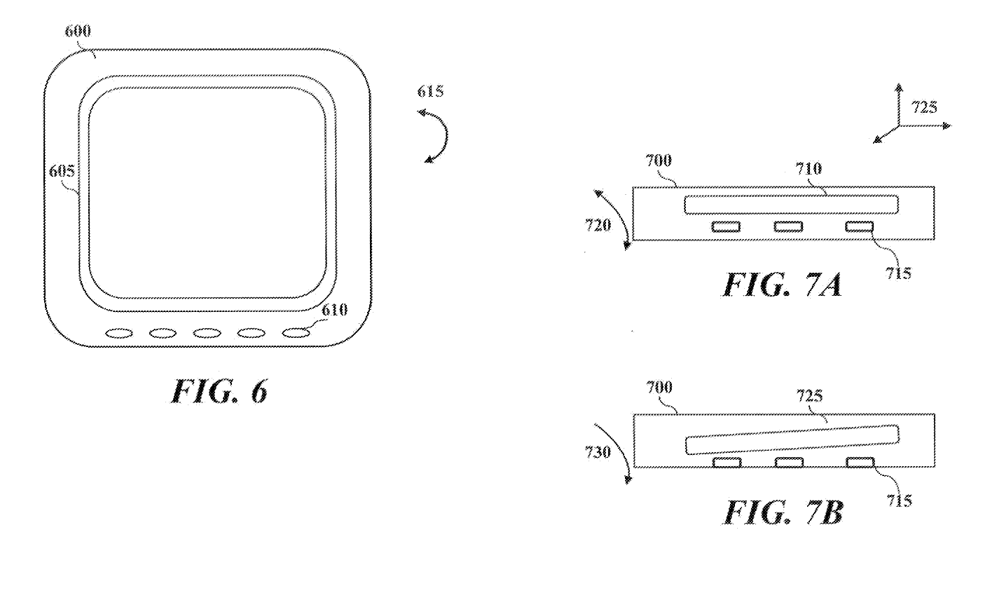

Referring now to FIG. 6, a graphical representation is depicted of a electronic device according to one embodiment. Electronic device 600 may relate to one or more of a eReader, media player, display device, gaming unit and electronic device in general. According to one embodiment ff the invention, device 600 may be configured to allow for movement of display 605 relative to device 600. In that fashion, electronic device 600 may allow for a user to operate and view display 605 while minimizing and/or canceling motion. As depicted, device 600 includes one or more buttons a user may employ for operating of device. In another embodiment, display 605 may be angularly displaced relative to the housing of device 600 as depicted by 615. In one embodiment, electronic device 600 may include one or more elements of the device stabilize described above in FIGS. 1-5.

Referring now to FIGS. 7A-7B, graphical representations are depicted of the electronic device according to one or more embodiments. Referring first to FIG. 7A, a graphical representation is depicted of the device of FIG. 6. Electronic device 700 includes display 710 and one or more elements depicted as 715. Elements 715 may relate to one or more of a dampening element and a counteracting element. In one embodiment, device 700 may allow for angular displacement of display 710 as depicted by 720. According to another embodiment, display 710 may move within the housing in three-dimensions as depicted by 725. For example, based on one or more of the housing of the device and display size, display 710 may be configured to move from 1 mm-2 cm.

Referring now to FIG. 7B, a graphical representation is depicted of a electronic device of FIG. 7A, wherein display 725 is displace as shown by direction 730. According to one embodiment of the invention, displacement of display 725 in direction 730 may be dampened by one or more of elements 715. According to another embodiment, display 725 may be returned to a starting position in a direction opposite to direction 730 by one or more counteracting elements, such as one or more of elements 715. In one embodiment, a counter force applied by one or more counteracting elements could be applied wherein the force gradually approaches zero in order to provide a smooth recovery. According to another embodiment, the electronic device may include a mechanism to temporarily stop the display in a particular position, such as a centered position. This is to avoid a dampening oscillating effect at the center position

While this disclosure has been particularly shown and described with references to exemplary embodiments thereof, it will be understood by those skilled in the art that various changes in form and details may be made therein without departing from the scope of the disclosure encompassed by the appended claims.

What is claimed is:

1. A device stabilizer comprising:
a housing;
a mounting structure for an electronic device, the mounting structure supported by the housing and configured to secure an electronic device;
a dampening element configured to stabilize motion of the mounting structure with respect to the housing; and
a counteracting element configured to control the arrangement of the mounting structure within the housing.

2. The device stabilizer of claim 1, wherein the mounting structure includes a slot configured to receive the electronic device.

3. The device stabilizer of claim 1, wherein the mounting structure is movable with respect to the housing.

4. The device stabilizer of claim 1, wherein the housing is configured to allow for angular displacement of the mounting structure.

5. The device stabilizer of claim 1, wherein the housing is configured to suspend the mounting structure to allow for movement.

6. The device stabilizer of claim 1, wherein the dampening element relates to one or more of an electrical and mechanical dampening element to absorb one or more external forces causing movement of the mounting structure.

7. The device stabilizer of claim 1, wherein the counteracting element is configured to apply a force to the mounting structure opposite to a direction of mounting structure movement.

8. The device stabilizer of claim 1, wherein the counteracting element is activated when an external force applied to the mounting structure is above a threshold.

9. The device stabilizer of claim 1, wherein the device stabilizer is configured to support one of an eReader, media player, and electronic device in general.

10. An electronic device, the device comprising:
a housing;
a display, the display supported by the housing;
a dampening element configured to stabilize motion of the display with respect to the housing; and
a counteracting element configured to control the arrangement of the display within the housing.

11. The electronic device of claim 1, wherein the display is movable with respect to the housing.

12. The electronic device of claim 1, wherein the housing is configured to allow for angular displacement of the display.

13. The electronic device of claim 1, wherein the housing is configured to suspend the mounting structure to allow for movement.

14. The electronic device of claim 1, wherein the dampening element relates to one or more of an electrical and mechanical dampening element.

15. The electronic device of claim 1, wherein the counteracting element is configured to apply a force opposite to movement of the mounting structure.

16. The electronic device of claim 1, wherein the counteracting element is activated when an external force applied to the display is above a threshold.

17. The electronic device of claim 1, wherein the device stabilizer is configured to support one of an eReader, media player, and electronic device in general.
